(19) United States
(12) Patent Application Publication
(10) Pub. No.: US 2023/0325549 A1
(43) Pub. Date: Oct. 12, 2023

(54) SYSTEM AND METHOD FOR AUTOMATIC FLOORPLAN GENERATION

(71) Applicant: Palo Alto Research Center Incorporated, Palo Alto, CA (US)

(72) Inventors: Eric A. Bier, Palo Alto, CA (US); Ritesh Sharma, Merced, CA (US)

(21) Appl. No.: 18/297,506

(22) Filed: Apr. 7, 2023

Related U.S. Application Data
(60) Provisional application No. 63/328,428, filed on Apr. 7, 2022.

(51) Int. Cl. G06F 30/13; G06T 19/20

(52) U.S. Cl. CPC G06F 30/13; G06T 19/20; G06T 2219/2016

(57) ABSTRACT

A system and method for automatic floorplan generation is provided. Mesh triangles are gathered for a space having one or more walls and a floor. A request for a floorplan for the space is received. A facing direction of the floor is determined from the mesh triangles. The mesh triangles are rotated until the floor is horizontal. A primary wall facing direction is also determined from the mesh triangles. The mesh triangles are rotated so the primary wall facing direction is parallel to a major axis or other desired direction. The floorplan is generated based on the floor and walls.

### FIELD

This application relates in general to 3D modeling and in particular to a system and method for automatic floorplan generation.

### BACKGROUND

Floorplans of a desired space are useful for navigating in a building, planning furniture placement, planning a remodel, planning the placement of pipes, wires, ducts, sensors and thermostats, and modeling the building for heating, ventilation, and air conditioning (HVAC) applications. However, producing a floorplan can be a time-consuming and expensive process that requires expert skills, including the measuring of distances and angles, and entering data into a CAD program, for example. Furthermore, this process may need to be performed more than once because the floorplan of a building can change over a period of time, such as when walls are moved, added, or removed, for example.

Accordingly, a system and method for automatically generating a floorplan is needed. Preferably, the floorplans are easily generated by users having little or no training.

### SUMMARY

Automatic floor plan generation should be able to be used by anyone capable of moving around in a building and looking at its walls, floors, and ceilings and require little or no training. A resulting automatic floorplan can show walls, chairs, tables, file cabinets, and other furniture and is automatically aligned with horizontal and vertical axes. If desired, a user can annotate the positions of sensors, thermostats, vents, doors, windows, and other objects and these will appear in the floorplan as well. A first style of floorplan can resemble a pen-and-ink diagram that shows features at different distances from the floor, and a second style of floorplan resembles a drafting diagram. Clutter in the space represented by the floor plan can be removed by recognizing walls in 3D space before projection to 2D. The resulting floorplan can include the positions of sensors, thermostats, vents, doors, windows, and other objects.

An embodiment provides a system and method for automatic floorplan generation. Mesh triangles are gathered for a space having one or more walls and a floor. A request for a floorplan for the space is received. A facing direction of the floor is determined from the mesh triangles. The mesh triangles are rotated until the floor is horizontal. A primary wall facing direction is also determined from the mesh triangles. The mesh triangles are rotated so the primary wall facing direction is parallel to a major axis or other desired direction. The floorplan is generated based on the floor and walls.

Still other embodiments will become readily apparent to those skilled in the art from the following detailed description, wherein are described embodiments by way of illustrating the best mode contemplated. As will be realized, other and different embodiments are possible and the embodiments' several details are capable of modifications in various obvious respects, all without departing from their spirit and the scope. Accordingly, the drawings and detailed description are to be regarded as illustrative in nature and not as restrictive.

### BRIEF DESCRIPTION OF THE DRAWINGS

FIG. 1 is a block diagram showing a system for automatic floorplan generation, in accordance with one embodiment.

FIG. 2 is a flow diagram showing a method for automatic floorplan generation, in accordance with one embodiment.

FIG. 3 is a block diagram showing, by way of example, a space for which mesh triangles are gathered via an augmented reality set.

FIG. 4 is a block diagram showing, by way of example, a portion of a space with a sensor object.

FIG. 5 is a block diagram showing, by way of example, a model of a space with a floor that is not initially level.

FIG. 6 is a graph showing, by way of example, a heat map of surface normal directions of the mesh triangles in spherical coordinates.

FIG. 7 is a graph showing, by way of example, a heat map 85 with defined cluster centers.

FIG. 8 is a block diagram showing, by way of example a display of a mesh model of a building space that is not aligned with coordinate axes.

FIG. 9 is a block diagram showing, by way of example, a display of the mesh model of FIG. 8 aligned along the coordinate axes.

FIG. 10 is a block diagram showing, by way of example, a mesh configuration gathered from a commercial building.

FIG. 11 is a block diagram showing, by way of example, wall segments identified via a DBScan.

FIG. 12 is a block diagram showing, by way of example, flat walls after rectangle construction and mesh replacement has been performed.

FIG. 13 is a block diagram showing, by way of example, a drafting-style floor plan that results from slicing the mesh of flat walls.

FIG. 14 is a block diagram showing, by way of example a mesh of a building interior that is sliced at multiple altitudes.

FIG. 15 is a block diagram showing, by way of example, a mesh model after floor and wall rotations.

FIG. 16 is a block diagram showing, by way of example, a pen-and-ink floorplan produced by slicing the mesh model of FIG. 15.

### DETAILED DESCRIPTION

Currently, obtaining a floorplan takes time and money due to requiring expert skill and the arduous task of measuring distances and angles within a space for which the floorplan is generated. Some floorplans can take days or longer to generate. To obtain floorplans at a lower cost and in a lesser amount of time, automatic floorplan generation can be utilized. Individuals, regardless of skill level and floorplan knowledge, can use the automatic floorplan generation to create drafting style floorplans and pen-and-ink floorplans.

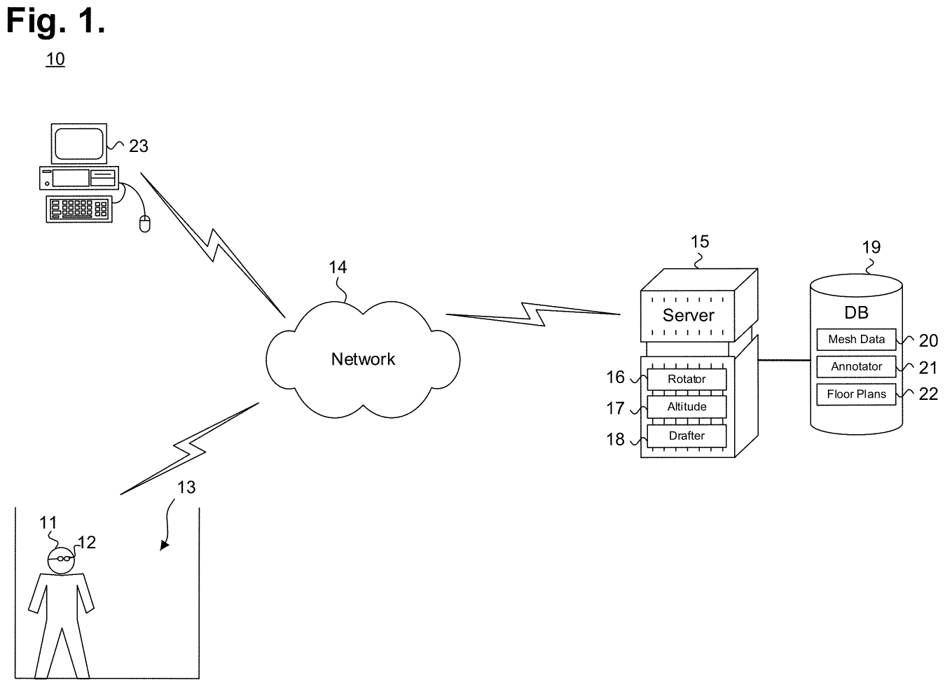

Automatic floorplan generation can utilize an augmented reality headset to obtain data regarding a space for which the floorplan is to be generated. FIG. 1 is a block diagram showing a system 10 for automatic floorplan generation, in accordance with one embodiment. A user 11 puts on an augmented reality headset 12, such as a Microsoft HoloLens 2, to obtain mesh data for a space 13 for which a floorplan is to be generated. The mesh data is transmitted to a server 15 via an internetwork 14. The server is interfaced with a database 19 and includes a processor to execute modules, including a rotator module 16, altitude determination module 17, and drafter module 18. The rotator 16 analyzes the mesh data and utilizes an algorithm to determine a position of a floor, which is rotated to be precisely horizontal. The rotator 16 also determines the directions of any walls and rotates the walls to align with Euclidian coordinates and uses the rotations of the floor and walls to apply to positions of any synthetic objects in the space.

The altitude module 17 utilizes an algorithm to determine an approximate altitude of a ceiling of the space from a histogram of triangle altitudes, and the drafter module 18 draws a floorplan of the space for output or display to the user, such as via a computing device 23 over the Internetwork 14. The computing device 23 can include a desktop computer or mobile computing device, such as a cellular phone, laptop, tablet, or other types of mobile computing devices.

In a further embodiment, the mesh triangle data and annotations can be processed to generate a floorplan via the augmented head set and provided to a different device for output. At a minimum, the headset should include a processor and wireless transceiver.

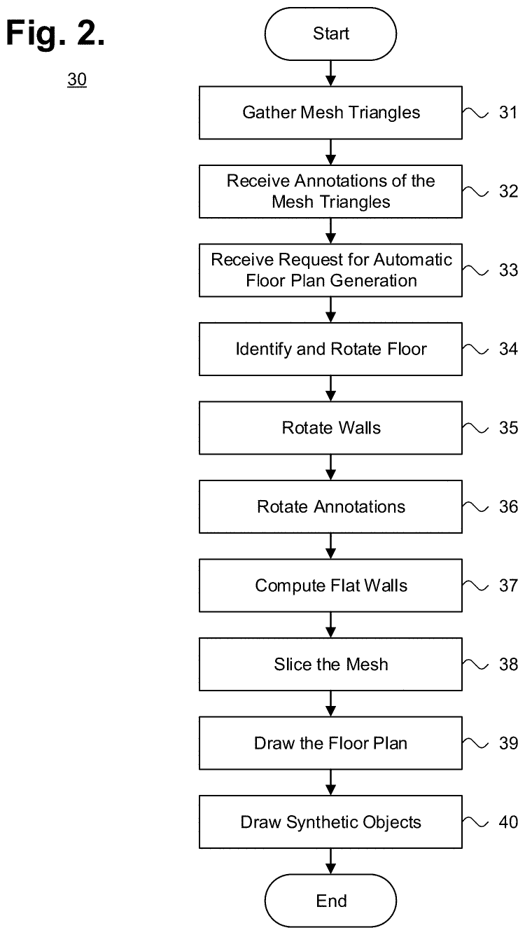

The mesh data utilized for generating the floorplan is obtained by moving around a space. FIG. 2 is a flow diagram showing a method 30 for automatic floorplan generation, in accordance with one embodiment. Automatic floorplan generation can commence via an individual user wearing an augmented reality headset that gathers (step 31) mesh triangles. Specifically, the user puts on the augmented reality headset, such as a Microsoft HoloLens 2, and walks around a space, such as in a building, for which a floorplan is desired. As the user walks, the headset displays mesh triangles where the headset detects walls, floors, ceilings, chairs, tables, file cabinets, or other objects within the space. The user continues walking and looking around the space until mesh triangles appear on all of the features that will be important to the floorplan. The mesh triangles viewed can be collected (step 31), transmitted, and stored for processing.

As the user walks around the space, the user can annotate the mesh triangles using eye gaze and voice commands to indicate the positions of objects, such as sensors, thermostats, vents, doors, windows, and other important objects. For example, the user can speak “that is a thermostat” when one is identified in the building space. A marker can then be added to the mesh data collected by the augmented reality headset at a location at which the user is gazing, for representation on a display. Further, sensors generate Bluetooth low energy signals that provide a MAC address of the respective sensor. When close enough, the HoloLens can find a sensor with a strong signal and obtain the MAC address for that sensor to get identification information for that sensor. The synthetic objects are displayed in the augmented reality view at these indicated positions. The annotations of the objects by the user can be collected (step 32), transmitted, and stored with or separate from the mesh triangles.

When sufficient mesh triangles and synthetic objects have been gathered, the user requests the automatic generation of a floorplan. The request is received (step 33), such as by a server, for processing. An algorithm can be used to discover a position (step 34) of a floor in the space using the mesh triangle orientation and dominant surface normal directions of the mesh triangles, as determined by k-means clustering in spherical coordinates. Subsequently, the floor of the mesh is rotated (step 34) to be precisely horizontal. The algorithm can also discover the dominant directions of the walls, if any, using another application of k-means clustering in spherical coordinates. The dominant walls are rotated (step 35) to align with Euclidian coordinates. The annotations are also rotated (step 36) based on the above rotation transformations, which are recorded and applied to positions of the synthetic objects, so they retain their relationship to the mesh.

If a drafting-style floorplan is desired, flat walls can be computed (step 37). Specifically, the walls can be recognized via an algorithm that applies a modified DBScan algorithm to the mesh triangles to find wall segments, discards wall segments that do not match a wall pattern, and replaces the mesh triangles, in each remaining wall segment, with rectangular blocks. If walls are not necessary to include in the floorplan, computing the walls can be skipped.

The mesh triangles can be sliced (step 38) to produce a set of line segments. In particular, the algorithm can determine an approximate altitude of a ceiling of the space from a histogram of triangle altitudes. A set of altitudes (y values) are chosen in the range from the floor to the ceiling. For example, this distance can be divided into n equal layers, for an integer n. At each altitude, a plane is constructed parallel to the floor at that altitude. The intersection of that plane is computed with the triangle mesh, producing a set of line segments.

Subsequently, the floorplan is drawn (step 39) by setting the y values of all line segments equal to 0, resulting in line segments in two dimensions. Specifically, in any given slice, all of the segments will have the same y value and that y value is the altitude of the slice. All the resulting line segments from all slices are drawn to form a single two-dimensional illustration, which is the floorplan. Finally, the synthetic objects are drawn (step 40). The y values of all synthetic objects are set equal to 0 and drawn onto the floorplan. Once generated, the floorplans can be provided to the user or a third party via a link, an attachment, or web access.

The resulting floorplan is automatically aligned with the horizontal and vertical axes and can show walls, chairs, tables, file cabinets, and other furniture. If desired, the user can annotate the positions of sensors, thermostats, vents, doors, windows, and other objects for display in the floorplan as well. A first style of floorplan can resemble a pen-and-ink diagram that shows features at different distances from the floor. A second style of floorplan can resemble a drafting diagram that removes clutter by recognizing walls in a 3D space before projection to 2D. Any user can generate the floorplans as long as an augmented reality headset and access to the floorplan generation algorithms are available.

### Gathering Mesh Triangles

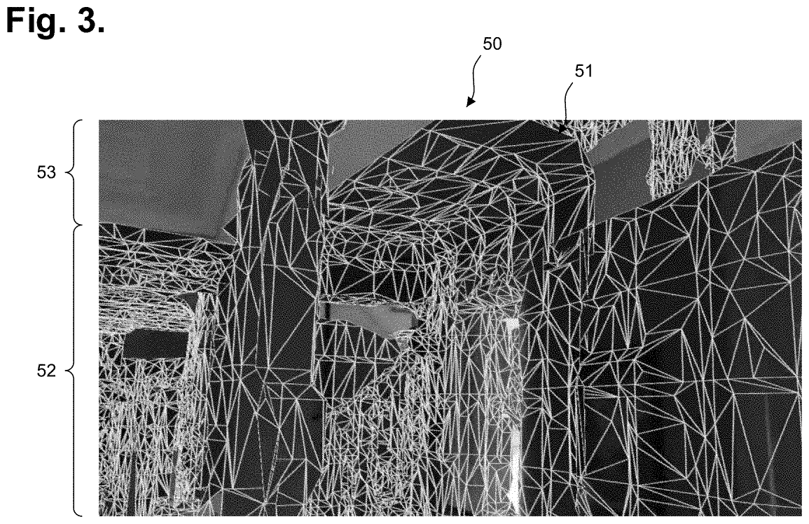

Augmented reality headsets, such as the HoloLens 2, come with hardware and software that constructs 3D triangles that represent the surrounding environment. These triangles can be displayed to the user as the user walks around in a space and looks in different directions. FIG. 3 is a block diagram showing, by way of example, a space 50 for which mesh triangles 51 are gathered via an augmented reality headset. As viewed from a user's perspective, the mesh triangles 51 can be overlaid on the user's view of a space, such as a building interior. The headset has already gathered many triangles 51 on the walls 52, but there are still regions of the walls and ceiling 53 where we see gaps that will be filled in as the user walks closer to those regions and looks at them from different points of view. When the gaps have been filled in, the mesh triangle data can be analyzed.

### Annotating the Mesh

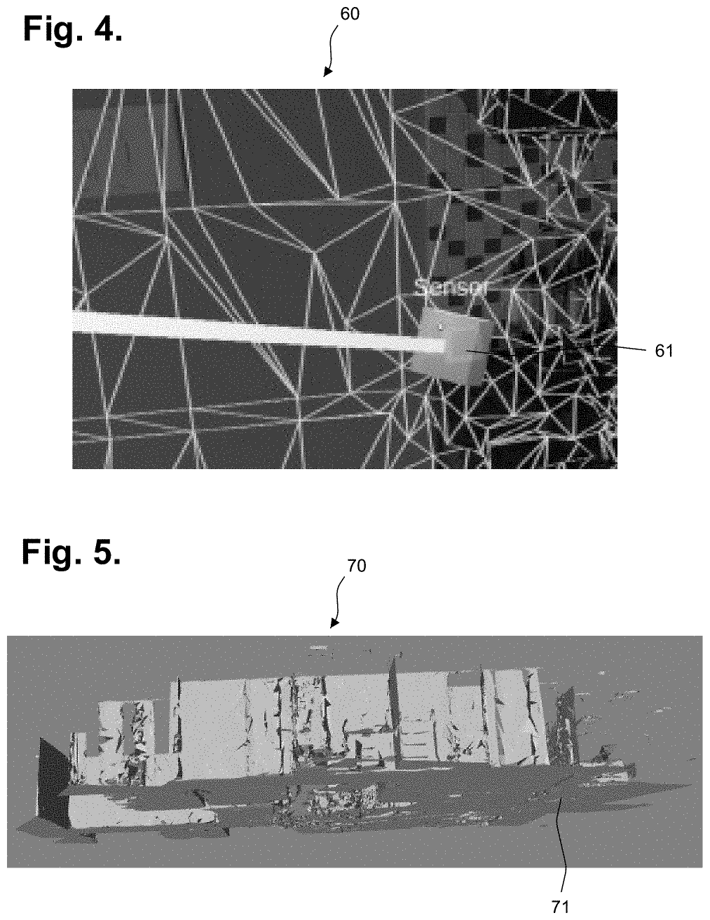

After gathering the mesh triangle data, the user can annotate objects in the space by indicating positions of important objects in the building interior, such as thermostats and sensors. The annotation can occur via eye gaze direction. With this method, the user looks at an object, such as a sensor, and gives some voice commands that tell the system: 1. The type of the object (e.g., a sensor) 2. The position of the object (the eye gaze point) 3. Any additional information (e.g., the type of sensor) and then tells the system to add a synthetic object at that position. FIG. 4 is a block diagram showing, by way of example, a portion of a space 60 with a sensor object 61. A synthetic object, such as the sensor 61, is identified and added by the user to the mesh triangle configuration.

### Requesting Floorplan Generation

Once the mesh triangle data and annotations of the objects are obtained, the user can request that a floorplan be generated. The request can be generated by giving voice commands to the augmented reality headset, by typing commands in a terminal window, or by interacting with a graphical user interface. Other processes for generating the request are also possible.

After receiving the request, the automatic floorplan generation system takes the triangle mesh and synthetic objects that the user has created and makes them available to the processing steps. Processing can be done on the augmented reality headset itself or the data can be moved to another computer for processing.

### Identifying and Rotating the Floor

To produce an accurate floorplan during processing, the automatic floorplan system can determine a facing direction and location of the floor. In one embodiment, the augmented reality headset already determines the rough direction of gravity from its built-in sensors. However, the direction may not be very accurate, so additional computation is needed. The floor direction can be determined by setting the rough gravity direction g_{rough} to be the negative y axis in which the mesh data is expressed. As the HoloLens creates the triangle mesh, higher y values are assigned to triangles that are located higher in the room and lower y values are assigned to triangles lower in the room. Accordingly, positive y direction is up, while the negative y direction is down. The final floor direction can be determined using g_{rough} and a true gravity or dominant direction, gₜᵣᵤₑ, as described below.

### Method 1: Using a Bounding Box

Often, one story of a building will be larger horizontally than vertically, the ceiling will be at a constant altitude, and the floor will be at a constant altitude. In such cases, the following steps can be performed: compute a bounding box of the entire mesh that fits the mesh tightly; find the minimum dimension of the bounding box, which will generally be the vertical dimension; and compute the surface normal of the top face of the bounding box that points towards the interior of the box. This is a good approximation of the true gravity direction, known as gₜᵣᵤₑ. Next, the mesh is rotated by the angle between gₜᵣᵤₑ and g_{rough} using a cross product of gₜᵣᵤₑ and g_{rough} as the axis of rotation. The floor will now be represented as horizontal.

### Method 2: Using Spherical K-Means

In a further embodiment, spherical k-means can be used to determine gₜᵣᵤₑ. For each triangle in the mesh, consider the surface normal vector that represents its facing direction. Each triangle has two such vectors and the one that faces toward the observer (away from the interior of a wall, for example) is selected. Discard any triangles where the facing direction is far from the positive y direction, such as more than 30 degrees from that direction. However, other angles are possible for determining a far direction from the positive y direction.

The remaining triangles are the ones that are most likely to be part of the floor. A spherical coordinates k-means algorithm can be used to find the dominant direction of this collection of triangles. Having found this direction, the triangles that are relatively far from the dominant direction can be discarded and the k-means algorithm is run again. The process of finding the dominant direction, discarding triangles, and running the k-means algorithm can be performed until the dominant direction converges. The dominant direction can be represented by gₜᵣᵤₑ. The mesh is then rotated by the angle between gₜᵣᵤₑ and g_{rough} using the cross product of gₜᵣᵤₑ and g_{rough} as the axis of rotation. The floor will now be represented as horizontal.

Now that the mesh is rotated for representing the floor as horizontal, the altitude of the floor along the y direction can be determined. To do this, the centroid of each mesh triangle whose facing direction is within a small angle of the positive y axis is determined or obtained. For each such centroid, consider its y coordinate. A histogram of all of these y coordinates, where each bucket represents a small distance, such as 2 inches, can be generated. The buckets can be considered in pairs, such as (0, 1), (1, 2), (2, 3) and so on. Pairs of buckets with the highest number of points in each bucket are identified.

If working on a single story of the space, two large bucket pairs, one near the bottom of the centroids and one near the top of the centroids can be identified. The bucket pair at the bottom of the centroids can represent the floor and the bucket pair near the top of the centroids can represent the ceiling. In case the building has some rooms with sunken floors and some with raised ceilings, a gap of several feet (e.g, the expected floor to ceiling height of a room) between the low spikes and the high spikes in the histogram can be identified. This allows the y values of the floor levels and the ceiling levels to be found. For the automatic floorplan generation, it is generally safe to take the highest of the floor levels and the lowest of the ceiling levels. The buckets can be considered in pairs or individually; however, in pairs, spikes are less likely to be missed in the histogram if the triangles happen to split fairly evenly across two neighboring buckets. FIG. 5 is a block diagram showing, by way of example, a model 70 of a space with a floor 71 that is not initially level. Using one of the methods described above, the floor can be corrected to be horizontal.

### Rotating the Walls

Next, the mesh model can be rotated so that the primary wall directions are aligned with the axes of Euclidian coordinates. The primary wall directions are first located and then, the model of the space in the floorplan is rotated. The primary wall directions can be located by first, optionally, removing from consideration any mesh triangles with surface normal that face nearly in the positive y or negative y directions. These are most likely ceiling or floor triangles. While this step is not necessary, it does reduce the number of triangles that need to be processed in subsequent steps and may speed up the processing. Next, the surface normals of the remaining triangles in spherical coordinates are identified. The surface normal is a 3D vector that points in a direction perpendicular to the plane of the triangle. The negative of a surface normal is also a surface normal, but one that points in the opposite direction. The HoloLens is consistent in the way its triangle vertices are ordered (clockwise or counter-clockwise), so the surface normal vectors can be chosen consistently. For example, all floor triangle surface normals point up, while all ceiling triangle surface normals point down.

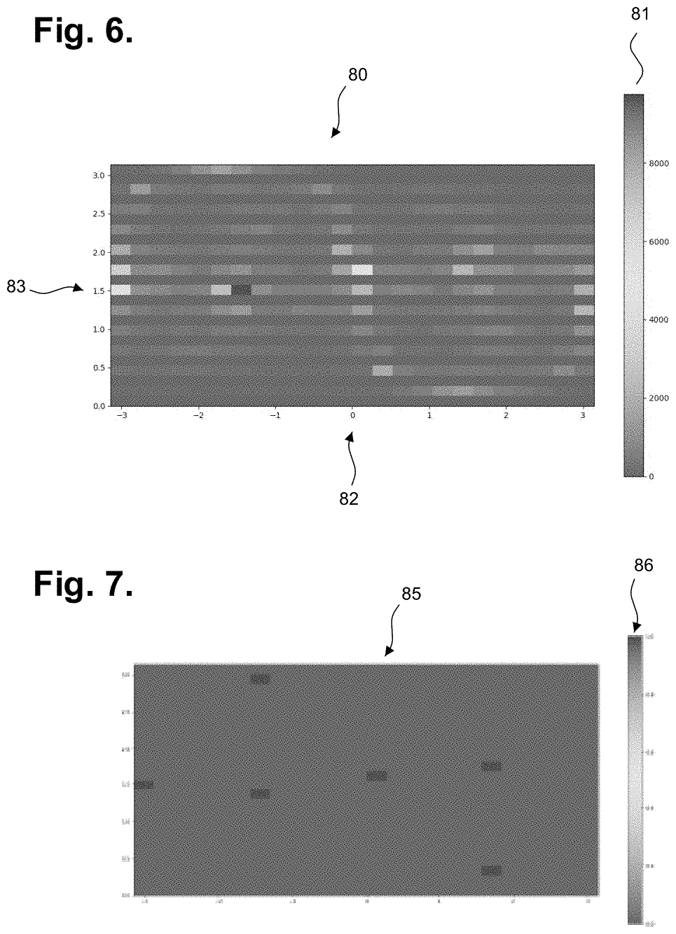

Each normal is then expressed in spherical coordinates. For example, the vectors in Euclidian coordinates [x, y, z] or vectors near Euclidian coordinates [x, y, z] are converted to spherical coordinates [theta, phi]. Spherical coordinates k-means clustering, such as described in Straub, Julian, Jason Chang, Oren Freifeld, and John Fisher III. “A Dirichlet process mixture model for spherical data.” In Artificial Intelligence and Statistics, pp. 930-938. PMLR, 2015, can be used to find the dominant wall directions. Assuming the building is designed with mainly perpendicular walls, there will be four dominant wall directions, so set k=4 for our k-means clustering. If working with a model that still has its floor and ceiling triangles, k can be set to k=6. The additional two primary directions are the floor and ceiling directions. FIG. 6 is a graph showing, by way of example, a heat map 80 of surface normal directions of the mesh triangles in spherical coordinates. In the heat map 80, a horizontal axis 82 represents the angle θ around the x-y plane, and the vertical axis 83 represents an angle Φ from the south pole to the north pole of the sphere of directions. The x-y plane is the set of all points such that y=0 and is a mathematical concept that is always present when data is represented as (x, y, z) points, as it is in any standard (Euclidian) 3D model. The North Pole is the set of all vectors for which x=0, z=0 and y>0. The South Pole is the set of all vectors for which x=0, z=0, and y<0.

A guide 81 can be provided adjacent to the heat map 80. The guide can display color and corresponding values to indicate a number of mesh triangles in each bucket of directions. Each rectangle in the heat map 80 represents a cluster of triangles that have surface normals that point in nearly the same direction. For instance, if a globe of planet Earth is visualized, a rectangle represents a small range of longitudes and a small range of latitudes. If the globe is placed so its center touches the wall of a house, that wall will face towards one of the longitude, latitude points on the globe, which are the spherical coordinates point for that wall. In one example, a cluster might represent all of the walls that are on the West side of their respective rooms.

As one can see in FIG. 4, there are many triangles in the models that are far from any cluster center. The rectangles that are coded a particular color, such as the most red or white, represent the biggest collections of triangles that face in the same directions. The big collection of triangles facing the same direction can be identified as cluster centers. Many triangles may be far from any cluster center for several reasons, including building interiors that have many objects that are not walls, floors, or ceilings, such as furniture, documents, office equipment, artwork, or other objects. These objects may be placed at many angles. The triangles can also be far from the cluster centers since the augmented reality headset generates triangles that bridge across multiple surfaces, such as triangles that touch more than one wall. For this reason, a modified version of spherical coordinates k-means clustering that ignores triangles that are outliers can be used.

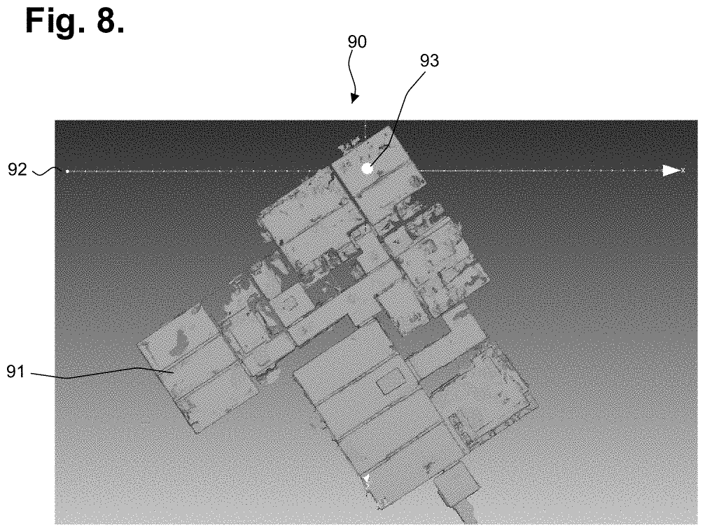

The k-means algorithm can be modified, such that after computing spherical coordinates k-means in the usual way, all triangles in each cluster whose facing direction is more than a threshold θ₁ from the cluster center are identified and discarded. Then, the k-means clustering can be run again and updated cluster centers are computed. All triangles that are more than θ₂ from each cluster center where θ₂<θ₁ can be discarded. This process can be repeated several times until a desired accuracy is achieved. For example, a sequence of angles θ₂: [60, 50, 40, 30, 20, 10, 5, 3] can be used, where the angles are in degrees. Once the modified spherical coordinates k-means algorithm completes, there will be 4 (or 6) cluster centers. Larger numbers can be used if the building has more wall directions, as is the case for buildings with diagonal walls, octagonal rooms, and similar more complicated geometries. FIG. 7 is a graph showing, by way of example, a heat map 85 with defined cluster centers 87. As described above with respect to FIG. 6, the heat map includes a horizontal axis that represents the angle θ around the x-z plan and the vertical axis that represents an angle Φ from the south pole to the north pole of the sphere of directions. The rectangles 87 in the heat map 85 represent buckets of mesh triangles. Using the color coded guide 86, which associates a color with numbers of mesh triangles, there are six distinct rectangles in the heat map for a k=6 case. The top rectangle represents the ceiling of the space modeled in the floorplan, while the four rectangles in the middle of the heat map represent four walls and the lowest rectangle represents the floor.

Once the primary wall directions are chosen, the cluster, which represents a set of walls that face in the same direction, with the largest number of triangles is selected and the direction is identified as θ_{wall}. The primary walls can be the walls that face West, North, East, or South for example. In that case, non-primary walls would face other directions like Southeast. The mesh is rotated by the angle between θ_{wall} and the x axis. After this operation, the primary walls will be pointing along the x axis. FIG. 8 is a block diagram showing, by way of example a display 90 of a mesh model 91 of a building space that is not aligned with coordinate axes 92. The coordinate axes 92 can run along a horizontal line and/or a vertical line. A point of reference 93 can be indicated on the building model and can be used as the center of rotation, to rotate the model 91 using the techniques described in detail above. Typically the point of reference is the place where the user started up the HoloLens. However, any point in the building interior should work fine.

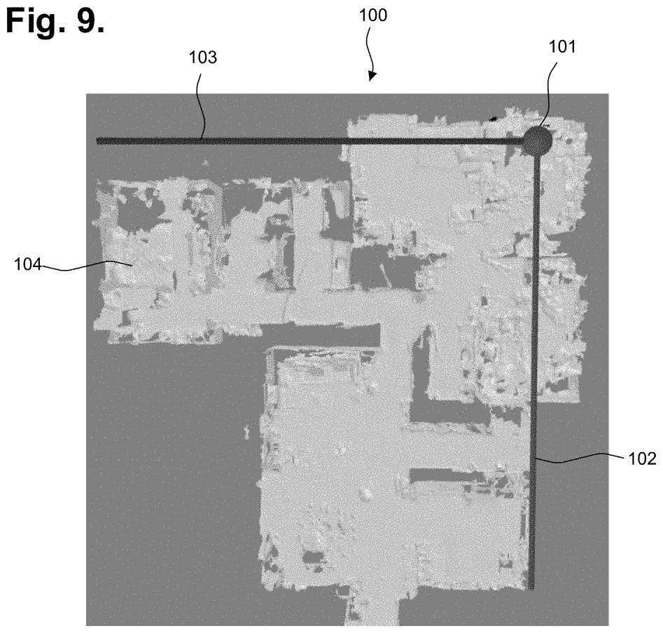

Specifically, the mesh model can be rotated for alignment along one or more coordinate axes. FIG. 9 is a block diagram showing, by way of example, a display 100 of the mesh model 104 of FIG. 8 aligned along the coordinate axes. One side of the mesh model is aligned with the horizontal coordinate axis shown in FIG. 8. The point of reference 101 is marked and x and y axes can be displayed over the mesh model 104. In one embodiment, the axes can be displayed as different colors to indicate the different axes. For example, the x axis can be red and the z axis can be blue, while the y axis can point toward a viewer. As shown, the walls are well aligned with the coordinate axes.

### Rotating the Annotations

If the user of the augmented reality application has annotated the building model, such as by adding marker objects to the model, such as the positions of sensors, doors, windows, vents, or other objects, these objects should appear in the correct positions in the final floorplan model. To determine these positions, the same transformation is applied to the markers for the objects as was applied to the mesh itself.

To rotate the markers for the objects, the floor leveling transformation can be represented as a matrix and the wall rotation can be represented as another matrix. The matrices are constructed so that simple matrix multiplication allows multiple transformations to be composed. If the floor leveling transformation matrix is A, and the wall rotation transformation matrix is B, the full transformation C=AB is computed and C is applied to the marker objects before displaying the markers to the user.

### Computing Flat Walls

To compute flat walls and separate the walls from furniture and other building contents wall directions are determined and a DBScan can be performed. For the wall directions, divide the triangles into those with similar facing directions, such as north, south, east and west, based on the surface normals of the triangles. For each wall direction, a modified DBScan algorithm can be performed and a centroid point of each triangle is computed. For each centroid point during DBScan, a number of other centroid points that are near enough to be considered neighbors is determined. However, instead of looking for neighbors in a sphere around the point, neighbors in a rectangular block centered on the point should be identified. The blocks should be tall enough to reach from the floor to the ceiling in the y direction, a little less wide than a door in the direction parallel to the proposed wall (e.g., 1.5 feet), and a few inches in the wall direction (to allow for some deviations from being perfectly flat). After running the DBScan, the mesh triangles can be grouped into wall segments.

Those wall segments that are not good candidate walls can be discarded. For example, walls that are too small, that don't come near enough to the floor, or that don't come near enough to the ceiling should be discarded. Subsequently, for each wall segment, a plane that has the same facing direction as the wall direction and is a good fit to the triangle centroids in that wall segment is identified. Given that the points are tightly collected in this direction, simply having the plane go through any centroid works surprisingly well. However, the point can also be chosen more carefully, such as finding a point at a median position in the wall direction.

For each remaining wall segment, rectangles can be constructed that lie in the fitted plane, are as wide as the wall segment triangles extend in width, and as tall as the wall segment triangles extend in height. For purposes of floorplan construction, the original mesh triangles can be discarded and replaced with the new rectangles to serve as a de-cluttered mesh. If the subsequent steps are based on libraries that expect a triangle mesh, two adjacent right triangles are used in place of each rectangle.

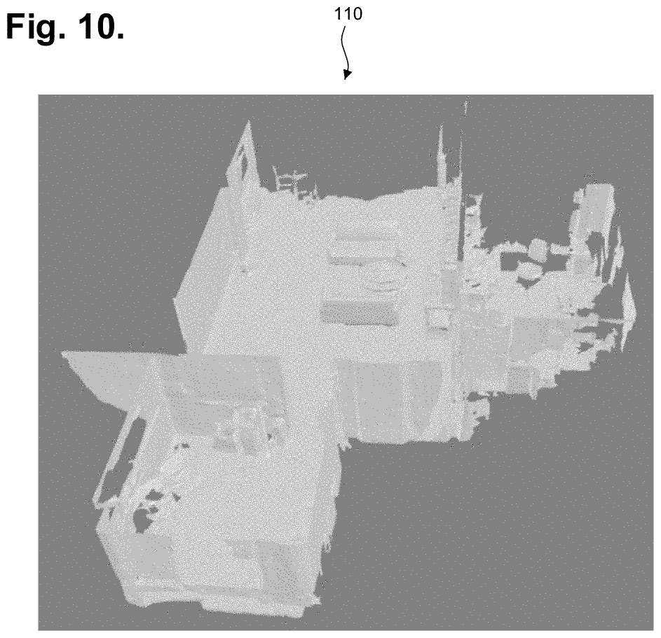

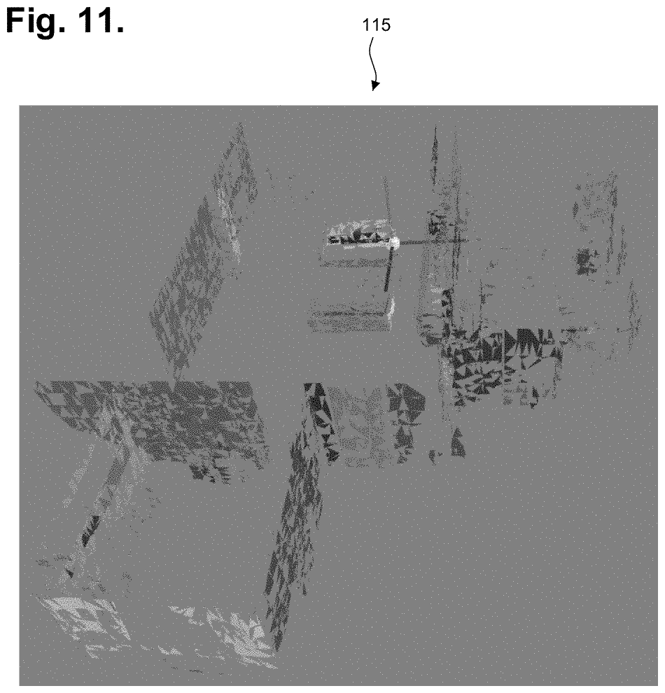

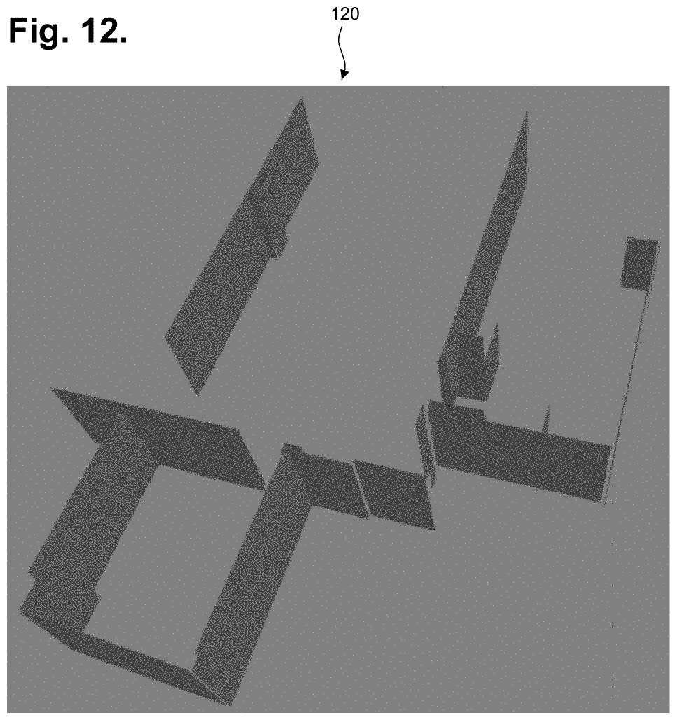

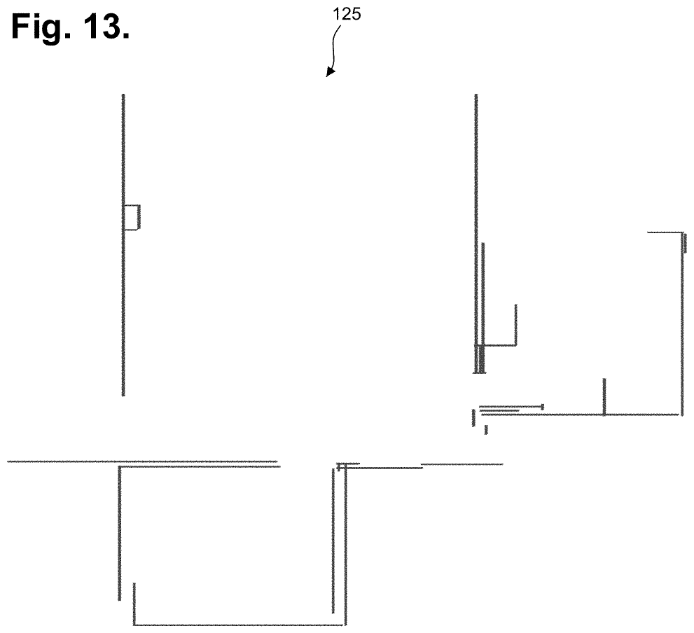

For example, during computation of the flat walls, a triangle mesh of an office building can be displayed. FIG. 10 is a block diagram showing, by way of example, a mesh configuration 110 gathered from a commercial building. A DBScan can be performed to identify the walls from the mesh triangles. FIG. 11 is a block diagram showing, by way of example, wall segments 115 identified via a DBScan. Different colors can be used to represent different wall segments. FIG. 12 is a block diagram showing, by way of example, flat walls 120 after rectangle construction and mesh replacement has been performed. Finally, FIG. 13 is a block diagram showing, by way of example, a drafting-style floor plan 125 that results from slicing the mesh of flat walls, using the method described below.

### Slicing the Mesh

Now that there is a mesh that is nicely aligned to the coordinate axes, the mesh can be sliced at several altitudes in order to produce a pen-and-ink floorplan. As described above, a histogram of y values allows the height of the floor or floors and the height of the ceiling or ceilings to be identified. A floor height, such as for the highest floor, is determined as the floor height y_{floor}. A ceiling height, such as for the lowest ceiling is determined as height y_{ceiling}. Then, a series of y values is selected between y_{floor} and y_{ceiling}, such as an even spacing of y values, where each yᵢ represents a single slice:

yᵢ=y_{floor}+(y_{ceiling}−y_{floor})*(i/n)

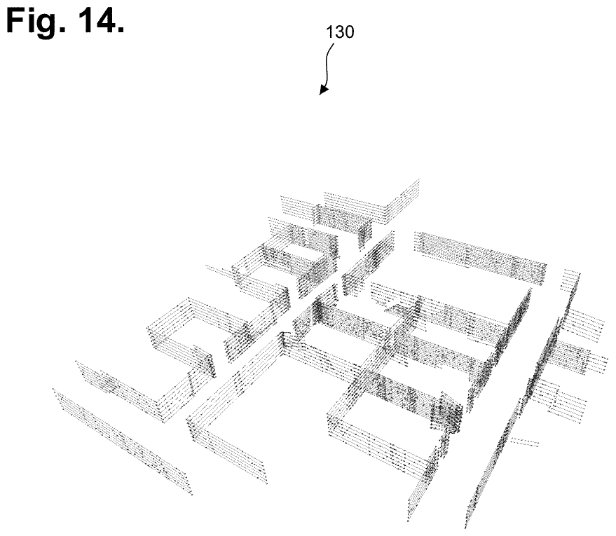

for each i such that 0≤i≤n. For slicing the mesh, the altitude of mesh is divided into n levels. Here, i represents each slice at a different altitude level. The plane which lies at an ith level is selected and a slice is computed to create a stack of slices. For each such yᵢ, the intersection of the mesh with the plane y=yᵢ is computed producing the stack of slices. FIG. 14 is a block diagram showing, by way of example a mesh of a building interior that is sliced at multiple altitudes.

### Drawing the Floorplan

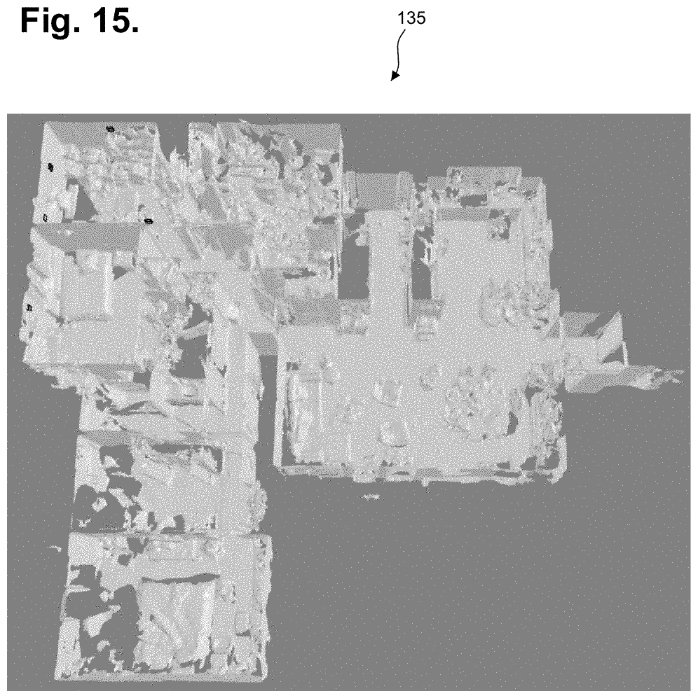

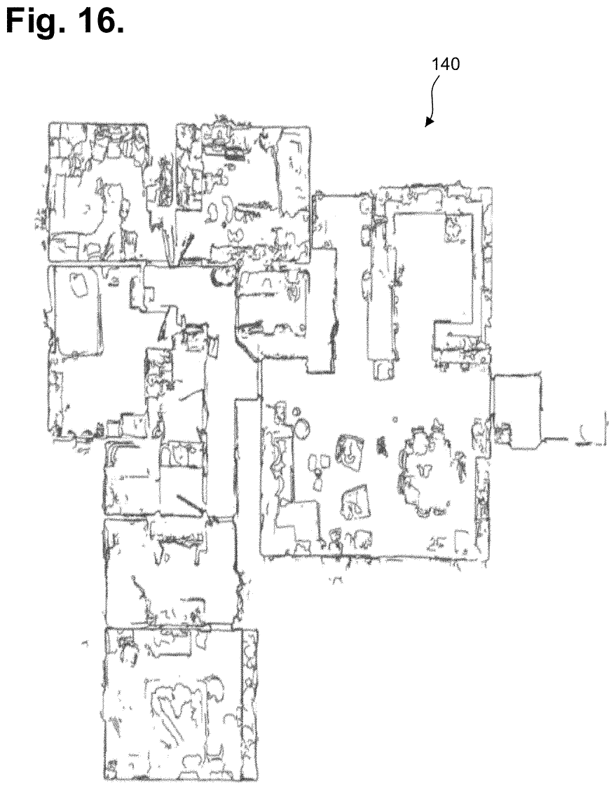

A two-dimensional floorplan can be produced by ignoring the y coordinates of the resulting line segments and plotting the resulting (x, z) coordinates as a two-dimensional image. FIG. 15 is a block diagram showing, by way of example, a mesh model after floor and wall rotations, while FIG. 16 is a block diagram showing, by way of example, a pen-and-ink floorplan produced by slicing the mesh model of FIG. 15. Optionally, each of the line segments can be drawn using a semi-transparent color, such as 50% opaque, to produce a floor plan that displays taller features in a darker color, while displaying shorter features in a lighter color. In a further embodiment, blocks that result from flat wall recognition can be sliced to produce a drafting style floorplan.

### Drawing Synthetic Objects

Shapes or colors can be used as markers to represent synthetic objects placed by the user to show the positions of sensors and other objects. As described above, the objects have been transformed by the matrix C, so they appear in the correct positions relative to the mesh. For example, in FIG. 16, the objects can be colored red and projected onto the same plane as the mesh slices so they appear in their correct positions relative to walls and other objects in the floorplan.

While the invention has been particularly shown and described as referenced to the embodiments thereof, those skilled in the art will understand that the foregoing and other changes in form and detail may be made therein without departing from the spirit and scope of the invention.

What is claimed is:

1. A method for automatic floorplan generation, comprising:
gathering mesh triangles for a space comprising one or more walls and a floor;
receiving a request for a floorplan for the space;
determining a facing direction of the floor from the mesh triangles;
rotating the mesh triangles until the floor is horizontal;
determining a primary wall facing direction from the mesh triangles;
rotating the mesh triangles so the primary wall facing direction is parallel to a major axis or other desired direction and
generating a floorplan based on the floor and walls.

2. A method according to claim 1, further comprising:
annotating the mesh triangles with locations of one or more objects by positioning each object relative to the mesh triangles that represent the space.

3. A method according to claim 2, further comprising:
rotating the objects that were positioned relative to the mesh triangles with each object maintaining its relative positions with respect to the mesh triangles.

4. A method according to claim 1, wherein the floor plan is a drafting-style floor plan.

5. A method according to claim 4, further comprising:
replacing the mesh triangles of the walls with rectangular blocks; and
generating the drafting-style floorplan based on the rectangular blocks.

6. A method according to claim 1, wherein the floorplan is a pen-and-ink floorplan.

7. A method according to claim 6, further comprising:
generating the pen-and-ink floorplan comprising slicing the mesh triangles using planes parallel to the floor at different altitudes.

8. A method according to claim 7, further comprising:
arranging slices from the mesh triangle slicing as a stack of the slices.

9. A method according to claim 1, further comprising:
adding one or more objects to the floorplan to represent objects within the space.

10. A method according to claim 1, wherein the objects each comprise one or more of a thermostat, sensor, and furniture.

11. A system for automatic floorplan generation, comprising:
a database comprising mesh triangles for a space comprising one or more walls and a floor; and
a server comprising a central processing unit, memory, an input port to receive the mesh triangles from the database, and an output port, wherein the central processing unit is configured to:
receive a request for a floorplan for the space;
determine a facing direction of the floor from the mesh triangles;
rotate the mesh triangles until the floor is horizontal;
determine a primary wall facing direction from the mesh triangles;
rotate the mesh triangles so the primary wall facing direction is parallel to a major axis or other desired direction and
generate a floorplan based on the floor and walls.

12. A system according to claim 11, wherein the central processing unit annotates the mesh triangles with locations of one or more objects by positioning each object relative to the mesh triangles that represent the space.

13. A system according to claim 12, wherein the central processing unit rotates the objects that were positioned relative to the mesh triangles with each object maintaining its relative positions with respect to the mesh triangles.

14. A method for automatic floorplan generating, comprising:
obtaining a collection of mesh data for a space comprising one or more walls, a floor, and ceiling;
reorienting the mesh data to generate a representation of the floor for a floorplan;
reorienting the mesh data to identify at least one of the walls as primary;
aligning a representation of the primary walls with coordinate axes;
identifying one or more annotations within the mesh data;
reorienting a representation of the annotations based on the floor and primary walls;
slicing the mesh data at one or more altitudes;
projecting slices from the sliced mesh data onto a plane; and
projecting the annotations on the plane.

15. A method according to claim 14, wherein the reorienting of the floor and the primary walls uses modified spherical coordinates k-means clustering.

16. A method according to claim 14, further comprising:
computing flat walls from the mesh data.

17. A method according to claim 16, wherein the flat walls are computed using a modified DBSCAN algorithm in three dimensions, wherein the modified DBSCAN algorithm uses a block-shaped neighborhood when counting neighboring points.

18. A method according to claim 14, wherein the mesh data is sliced at a set of altitudes evenly spaced between the ceiling and floor.

19. A method according to claim 18, wherein the sliced mesh data is projected onto the same plane to produce a composite line drawings of the three-dimensional field.

20. A method according to claim 18, where the sliced mesh data is drawn in a semi-transparent color to produce a composite line drawing that displays tall flat features in a dark color and short rounded features in a light color.
